(19) United States
(12) Patent Application Publication
(10) Pub. No.: US 2024/0014067 A1
(43) Pub. Date: Jan. 11, 2024

(54) SEMICONDUCTOR DEVICE AND METHOD OF MANUFACTURING THE SAME

(71) Applicant: RENESAS ELECTRONICS CORPORATION, Tokyo (JP)

(72) Inventors: Hiroyuki ARIE, Tokyo (JP); Takayuki IGARASHI, Tokyo (JP)

(21) Appl. No.: 18/319,248

(22) Filed: May 17, 2023

(30) Foreign Application Priority Data
Jul. 5, 2022 (JP) 2022-108449

(51) Int. Cl. H01L 21/762; H01L 27/12

(52) U.S. Cl. CPC H01L 21/76283; H01L 27/1203

(57) ABSTRACT

A semiconductor device having a semiconductor substrate, a BOX film on the semiconductor substrate, a semiconductor layer on the BOX film, a first trench penetrated through the semiconductor layer and reached to the first insulating film, a first insulating film covering a side surface of the first trench and in contact with an upper surface of the BOX film at a bottom of the first trench, a second trench formed at the bottom of the first trench such that the second trench penetrates through the first insulating film and reached in the BOX film, a second insulating film filled in the first trench and the second trench. A bottom surface of the second trench is located in the BOX film below an interface between the semiconductor layer and the BOX film, and a void is located in the second insulating film at the same height the interface.

### CROSS-REFERENCE TO RELATED APPLICATIONS

The disclosure of Japanese Patent Application No. 2022-108449 filed on Jul. 5, 2022, including the specification, drawings and abstract is incorporated herein by reference in its entirety.

### BACKGROUND

The present disclosure relates to a semiconductor device and method of manufacturing the same and, more particularly, it relates to a technique effectively applied to the semiconductor device having DTI and method of manufacturing the same.

The semiconductor device having an SOI substrate is currently used as a semiconductor device capable of suppressing short-channel properties of transistors and suppressing device variation. The SOI substrate is a substrate in which a BOX (Buried Oxide) film is formed on a support substrate made of high-resistance Si (silicon) or the like, and a thin semiconductor layer (silicon layer, SOI layer) mainly containing Si (silicon) is formed on the BOX film.

Further, as a structure for an electrically isolating element formed in a semiconductor substrate, it is known to form an element isolation film in which an insulating film is filled in a trench formed in an upper surface of the semiconductor substrate.

For example, Japanese Patent Laid-Open No. JP-A-2011-2011 (Patent Document 1) describes forming the element isolation film on the upper surface of the semiconductor substrate and further forming the element isolation film having a void therein in the trench deeper than the element isolation film.

### SUMMARY

When a semiconductor device is mounted on an SOI substrate, it is conceivable to form a deep element isolation film, that is, a DTI, which penetrates through a semiconductor layer on a BOX film and contacts with an upper surface of the BOX film. However, even if the semiconductor layer is completely isolated by the element isolation film, a leakage current may flow through an interface (oxide film interface) between a bottom surface of element isolation film and the BOX film. In this case, a breakdown voltage of the device cannot be ensured, and the reliability of the semiconductor device is lowered.

Other objects and novel features will become apparent from the description of this specification and the accompanying drawings.

The typical ones of the embodiments disclosed in the present application will be briefly described as follows.

A semiconductor device according to an embodiment includes a semiconductor substrate, a first insulating film on the semiconductor substrate, a semiconductor layer on the first insulating film, a first trench extending from an upper surface of the semiconductor layer to an upper surface of the first insulating film, a second insulating film covering side surface of the first trench and in contact with the upper surface of the first insulating film at a bottom of the first trench, a second trench formed between the second insulating film opposed to each other in the first trench, and having a bottom surface located in the first insulating film below the lower between the second insulating film and the first insulating film, a third insulating film embedded in the second trench, and a void enclosed in the third insulating film and partially located at the same height as the interface.

A manufacturing method of the semiconductor device, which is an embodiment, includes a step of preparing an SOI substrate including the first insulating film and the semiconductor layer sequentially formed on the semiconductor substrate, a step of forming the first trench reaching an upper surface of the first insulating film from an upper surface of the semiconductor layer, a step of forming the second insulating film covering the side surface and the bottom surface of the first trench, a step of forming the second trench penetrating the second insulating film in a direction perpendicular to the upper surface of the semiconductor layer and reaching a middle depth of the first insulating film, and a step of forming the third insulating film filling an inside of the second trench and including the void. A portion of the void is located at the same height as an interface between the first insulating film and the second insulating film.

According to an embodiment disclosed in this application, the reliability of the semiconductor device can be improved.

### BRIEF DESCRIPTION OF THE DRAWINGS

FIG. 1 is a cross-sectional view illustrating a semiconductor device according to a first embodiment.

FIG. 2 is a cross-sectional view during a manufacturing process of the semiconductor device according to the first embodiment.

FIG. 3 is a cross-sectional view during the manufacturing process of the semiconductor device after the step shown in FIG. 2.

FIG. 4 is a cross-sectional view during the manufacturing process of the semiconductor device after the step shown in FIG. 3.

FIG. 5 is a cross-sectional view during the manufacturing process of the semiconductor device after the step shown in FIG. 4.

FIG. 6 is a cross-sectional view during the manufacturing process of the semiconductor device after the step shown in FIG. 5.

FIG. 7 is a cross-sectional view during the manufacturing process of the semiconductor device after the step shown in FIG. 6.

FIG. 8 is a cross-sectional view during the manufacturing process of the semiconductor device after the step shown in FIG. 7.

FIG. 9 is a cross-sectional view illustrating a semiconductor device according to a second embodiment.

FIG. 10 is a cross-sectional view during a manufacturing process of the semiconductor device according to the second embodiment.

FIG. 11 is a cross-sectional view during the manufacturing process of the semiconductor device after the step shown in FIG. 10.

FIG. 12 is a cross-sectional view during the manufacturing process of the semiconductor device after the step shown in FIG. 11.

FIG. 13 is a cross-sectional view during the manufacturing process of the semiconductor device after the step shown in FIG. 12.

FIG. 14 is a cross-sectional view during the manufacturing process of the semiconductor device after the step shown in FIG. 13.

FIG. 15 is a cross-sectional view illustrating a semiconductor device according to a third embodiment.

FIG. 16 is a cross-sectional view during a manufacturing process of the semiconductor device according to the third embodiment.

FIG. 17 is a cross-sectional view during the manufacturing process of the semiconductor device after the step shown in FIG. 16.

FIG. 18 is a cross-sectional view during the manufacturing process of the semiconductor device after the step shown in FIG. 17.

FIG. 19 is a cross-sectional view of a main portion showing a semiconductor device of a comparative example.

### DETAILED DESCRIPTION

In following embodiments, when required for convenience, the description will be made by dividing into a plurality of sections or embodiments, but except when specifically stated, they are not independent of each other, and one is related to the modified example, detail, supplementary description, or the like of part or all of the other. In addition, in the following embodiments, the number of elements or the like (including the number, the number, the amount, the range, and the like) is not limited to the mentioned number, except the case where it is specified in particular or the case where it is obviously limited to a specific number in principle, and may be equal to or more than the mentioned number or may be equal to or less than the mentioned number.

Furthermore, in the following embodiments, the constituent elements (including element steps and the like) are not necessarily essential except for the case in which they are specifically specified, the case in which they are considered to be obviously essential in principle, and the like. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In this application, a stacked substrate including a semiconductor substrate, a BOX film and a semiconductor layer sequentially stacked thereon is referred to as the SOI (Silicon On Insulator) substrate. The semiconductor layer on the BOX film may be referred to as a SOI layer.

### First Embodiment

(Structure of Semiconductor Device in First Embodiment)

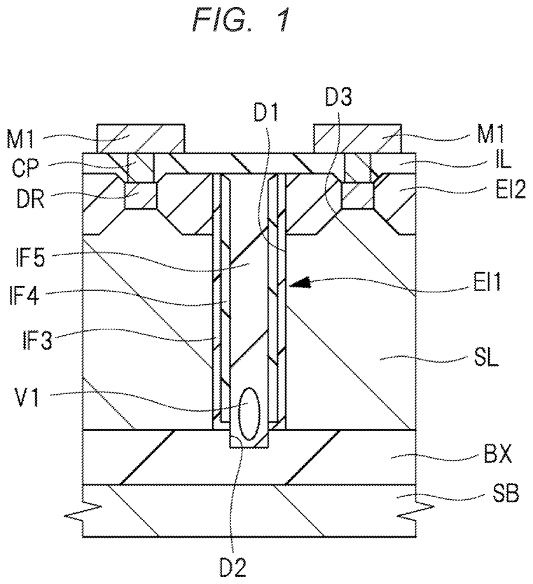

A structure of a DTI (Deep Trench Isolation) formed on an SOI substrate in the present embodiment will be described below with reference to FIG. 1. FIG. 1 shows a cross-sectional view illustrating a semiconductor device according to the present embodiment.

As shown in FIG. 1, the semiconductor device of the present embodiment has a substrate composed of a semiconductor substrate SB as a support SOI substrate, a BOX film BX on the semiconductor substrate SB, and a semiconductor layer as a SOI layer on the BOX film BX. The semiconductor substrate SB is a monocrystalline silicon substrate having a thickness of, for example, approximately 500 to 700 micrometers and having a high resistance of, for example, 750 ohm centimeter or more. The BOX film BX is formed of, for example, a silicon oxide film (SiO2 film). A thickness of the BOX film BX is, for example, greater than 0.5 micrometers. A semiconductor layer SL is semiconductor layer made of the monocrystalline silicon. A thickness of the semiconductor layer SL is, for example, 5 micrometers. The semiconductor substrate SB may be connected to a ground potential.

A plurality of semiconductor elements is formed on the semiconductor layer SL. The semiconductor elements here is, for example, MOSFET (Metal Oxide Semiconductor Field Effect Transistor). The semiconductor elements are separated from each other by an element isolation film EI2 made of an insulating film filled in a relatively shallow trench (isolation trench) D3 formed in an upper surface of the semiconductor layer SL. The element isolation film EI2 is, for example, mainly composed of silicon oxide.

A semiconductor region (diffused region) DR in which impurities are introduced at a middle depth is formed in the upper surface of the semiconductor layer SL exposed from the element isolation film EI2. The semiconductor region DR constitute, for example, a source region and a drain region of MOSFET or a contact layer for fixing the semiconductor layer SL at a predetermined potential. An interlayer insulating film IL is formed on each of the semiconductor layer SL and the element isolation film EI2 and the semiconductor region DR. The interlayer insulating film IL mainly made of silicon oxide. An upper surface of the interlayer insulating film IL is planarized.

The interlayer insulating film IL has a plurality of connecting holes that penetrating from an upper surface to a bottom surface. The connecting holes exposes an upper surface of the semiconductor region DR at a bottom thereof. A contact plug CP are filled in the respective connecting holes. The contact plug CP is, for example, a conductive connecting portion mainly made of W (tungsten). Although not shown in the drawings, a silicide layer may be formed between the contact plug CP and the semiconductor region DR to reduce the connecting resistivity.

A plurality of wirings M1 made of metal film are formed on the interlayer insulating film IL and the contact plug CP. The wiring M1 is made of, for example, Cu (copper) or Al (aluminum). The contact plug CP is connected to an upper surface of the wiring M1. That is, the semiconductor region DR is electrically connected to the wiring M1 via the contact plug CP. Although not shown, a side surface of the wiring M1 may be covered with an insulating film constituting wiring layer, and a plurality of wiring layers may be laminated on wiring layer.

In addition to the element isolation film EI2, the semiconductor device of the present embodiment has a deeper element isolation film EI1 than the element isolation film EI2. A portion of the element isolation film EI1 is formed in a trench D1 that penetrates vertical direction through the element isolation film EI2 and the semiconductor layer SL below the element isolation film EI2 and reaching the BOX film BX. The vertical direction is a direction (vertical direction, thickness direction, height direction, depth direction) perpendicular to the upper surface of the semiconductor layer SL.

The trench D1 extends along the upper surface of the semiconductor layer SL. That is, the trench D1 extends in a depth direction of FIG. 1. Another part of the element isolation film EI1 is formed in a trench D2 described later. The trench D1 penetrates from the upper surface to a bottom surface of the semiconductor layer SL. The bottom surface of the trench D1 reaches an upper surface of the BOX film BX. That is, the trench D1 is deeper than the trench D3 and the element isolation film EI2. A p-type impurity (for example, B (boron)) is introduced into the semiconductor layer SL on a side surface of the trench D1.

In the trench D1, an insulating film IF3 is formed on the side surface and the bottom surface (upper surface of the BOX film BX) of the trench D1 so as to continuously cover the side surface and the bottom surface of the trench D1. The insulating film IF3 is made of, for example, silicon oxide. The insulating film IF3 does not cover the entire bottom surface of the trench D1, and exposes a central portion of the bottom surface. A bottom surface of the insulating film IF3 is in contact with the upper surface of the BOX film BX. A width of the insulating film IF3 in contact with the BOX film BX in a short direction of the trench D1 in plan view is about 800 nm or less. In the short direction, the insulating film IF3 is separated into two portions by the trench D2 and an insulating film IF5, which will be described later. Here, the width of the insulating film IF3 in contact with the BOX film BX is a width of the structure including the two separated insulating films IF3. The width of the insulating film IF3 is synonymous with a width of the lower end of the trench D1 in the short direction of the trench D1.

Further, the side surface of the trench D1 is covered with an insulating film IF4 via the insulating film IF3. The insulating film IF4 continuously covers the surface of the insulating film IF3 that is opposite to a side surface of the semiconductor layer SL and an upper surface of the insulating film IF3 that covers the bottom surface of the trench D1. In a direction (lateral direction) along the upper surface of the semiconductor layer SL, a central end portion of the trench D1 of each end portions of the insulating films IF3 and IF4 terminates at the same distance from the center of the trench D1. In other words, in plan view, the central end portion of the respective trench D1 of the insulating films IF3 and IF4 overlap each other. The insulating film IF4 is made of, for example, silicon oxide.

A central side surface (terminal portion) of the insulating film IF4 in the trench D1 and a central terminal portion of the insulating film IF3 in the trench D1 configure a side surface of the trench D2. The trench D2 is a concave portion deeper than the trench D1, reaching from a vicinity of the upper surface of the semiconductor layer SL into the BOX film BX near the semiconductor substrate SB below an interface between the insulating film IF3 and the BOX film BX. That is, a bottom surface of the trench D2 is located below the interface between the insulating film IF3 and the BOX film BX. In other words, the trench D2 reaches a middle depth of the BOX film BX. The side surface of the trench D2 is configured by a side surface of the insulating film IF4, a side surface of the insulating film IF3, and a side surface of the BOX film BX in this order from the top. The side surface of the trench D2 is mainly constituted by the side surface of the insulating film IF4. The trench D2 extends along the upper surface of the semiconductor layer SL. That is, the trench D2 extends in the depth direction of FIG. 1.

An insulating film IF5 including a void V1 is filled in the trench D2. The insulating film IF5 is filled between the insulating film IF4 covering the side surface of the trench D1. That is, the insulating films IF3, IF4 and IF5 are sequentially formed in the trench D1 from the side surface toward the central. Upper ends of the insulating films IF3, IF4 and IF5 are located at substantially the same height as upper surfaces of the element isolation film EI2 and the semiconductor layer SL. The insulating films IF3, IF4 and IF5 are not formed on the upper surfaces of the element isolation film EI2 and the semiconductor layer SL respectively. A lower end of the insulating film IF5 is in contact with a bottom surface of the BOX film BX at a bottom of the trench D2. That is, the insulating film IF5 is filled in the trench D2 below the bottom surface of the trench D1. The insulating film IF5 is made of, for example, silicon oxide.

The void V1 is formed in the trench D2 vicinity the bottom of the trench D2. An entire periphery of the void V1 is covered with the insulating film IF5. That is, the void V1 does not touch the film other than the insulating film IF5, and is separated from the side surface and the bottom surface of the trench D2. At least a part of the void V1 is located at the same height as the interface between the insulating film IF3 and the BOX film BX and an interface between the semiconductor layer SL and the BOX film BX.

The insulating films IF3, IF4 and IF5, and the void V1 in the trenches D1 and D2 constitute the element isolation film EI1. The element isolation film EI1 is a device isolation structure (device isolation area) that is deeper than the element isolation film EI2, and is a so-called DTI. Note that the trenches D1 and D2 may also be considered to constitute the element isolation film EI1. The element isolation film EI1 electrically separates the plurality of semiconductor elements formed (mounted) on the semiconductor layer SL.

Here, although the element isolation film EI1 has been described as having one void V1 in structure, one or more other voids may be formed in the insulating film IF5 on the void V1.

(Method of Manufacturing Semiconductor Device in First Embodiment)

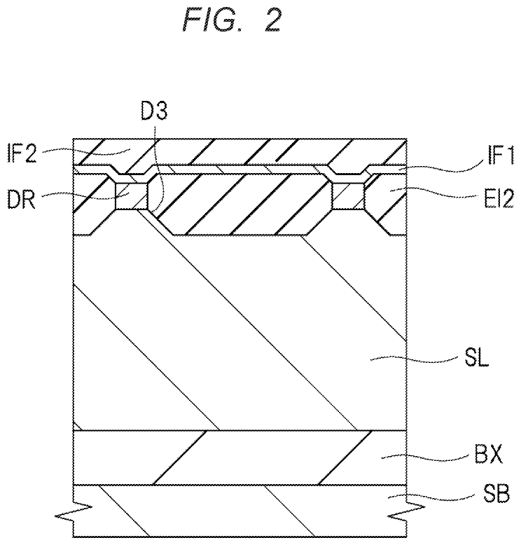

A method of manufacturing semiconductor device according to first embodiment will be described below referring to FIGS. 2 to 8 and 1. FIG. 2 to FIG. 8 are cross-sectional views during a manufacturing process of present embodiment.

First, as shown in FIG. 2, the semiconductor substrate SB in which the BOX film BX and the semiconductor layer SL are stacked in this order is prepared. The semiconductor substrate SB is a support substrate made of Si (silicon), the BOX film BX on the semiconductor substrate SB is a silicon oxide film, and the semiconductor layer SL on the BOX film BX is a layer made of single crystal silicon. A thickness of the BOX film BX is 0.2 to 2 micrometers. Here, the thickness of the BOX film BX is, for example, 1.5 micrometers. A thickness of the semiconductor layer SL is 0.5 to 15 micrometers. Here, the thickness of the semiconductor layer SL is 5 micrometers.

The SOI substrate configured of the semiconductor substrate SB, the BOX film BX and semiconductor layer SL can be formed by SIMOX (Silicon Implanted Oxide) method. That is, O2 (oxygen) is ion-implanted with high energy into an upper surface of the semiconductor substrate SB made of Si (silicon), and then heat treatment is performed to form a buried oxide film (BOX film) at a position slightly deeper than the upper surface of the semiconductor substrate SB, whereby the SOI substrate can be formed. Further, the SOI substrate can be formed by bonding the semiconductor substrate SB having an oxide film formed thereon and the semiconductor substrate SB made of another Si (silicon) by applying high heat and pressure, and then polishing a silicon layer on one side to form a thin film.

Subsequently, the element isolation film EI2 is formed using known methods. The element isolation film EI2 is formed on an upper surface of the SOI substrate, and is configured of an insulating film filled in the trench D3 that reaches halfway through the semiconductor substrate SB. The element isolation film EI2 has, for example, STI (Shallow Trench Isolation) structure and is configured mainly of silicon oxide. Here, the element isolation film EI2 including STI structure is described, but the element isolation film EI2 may have LOCOS (LOCal Oxidation of Silicon) structure.

Subsequently, the insulating films IF1 and IF2 is sequentially formed on the semiconductor layer SL and the element isolation film EI2. The insulating film IF1 is made of, for example, silicon nitride (Si3N4). The insulating film IF2 is made of, for example, silicon oxide. The insulating films IF1 and IF2 can be formed by, for example, CVD (Chemical Vapor Deposition).

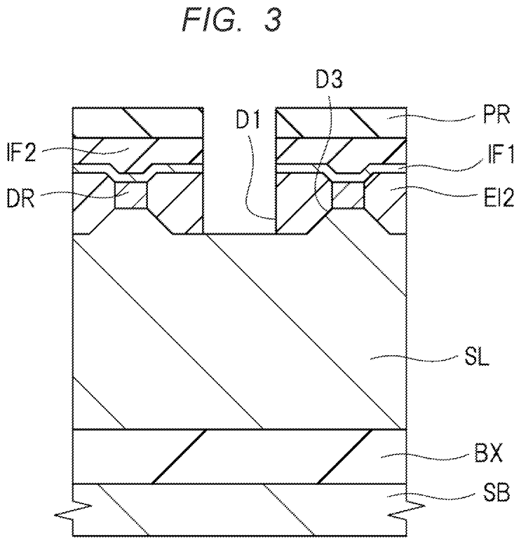

Next, as shown in FIG. 3, a photoresist film PR is formed on the insulating film IF2. The photoresist film PR is a resist pattern having an opening directly above the element isolation film EI2. Subsequently, using the photoresist film PR as a mask (anti-etching mask), part of each of the insulating films IF1 and IF2, and the element isolation film EI2 is removed. As a result, the upper surface of the semiconductor layer SL, which is a bottom surface of the trench D3, is exposed. Thus, the trench D1 is formed.

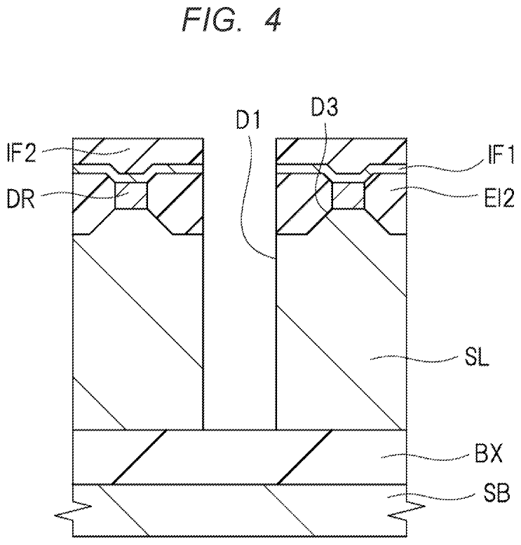

Next, as shown in FIG. 4, after the photoresist film PR is removed, dry etching is performed using the insulating films IF1 and IF2 as a hard mask. As a result, a portion of the semiconductor layer SL is removed from the bottom surface of the trench D3 over the upper surface of the BOX film BX. That is, the trench D1 is dug down so that the trench D1 reaches the BOX film BX. This step exposes the upper surface of the BOX film BX. Since silicon is selectively removed, the BOX film BX, which is an insulating film made of silicon oxide, serves as an etch stopper. Therefore, the upper surface of the BOX film BX is not substantially receded and remains flat.

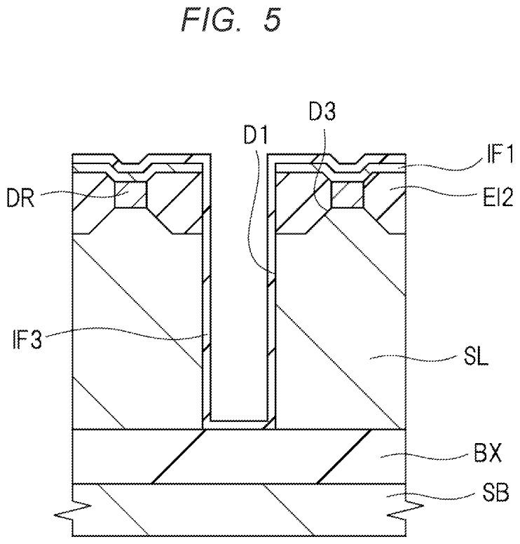

Next, as shown in FIG. 5, the insulating film IF2 is removed. Subsequently, the insulating film IF3 is formed (deposited) so as to cover the semiconductor layer SL including the side surface and the bottom surface of the trench D1 and the insulating film IF1. The insulating film IF3 is made of, for example, silicon oxide. The insulating film IF3 can be formed by, for example, a CVD method. A thickness of the insulating film IF3 is smaller than half of an opening the width of the trench D1. Therefore, the insulating film IF3 covering the side surface of the trench D1 are separated from each other.

Subsequently, a p-type impurity (for example, B (boron)) is implanted into the side surface of the trench D1 by an ion-implantation method. In this method, the upper surface of the semiconductor layer SL is implanted obliquely to introduce impurities, that is, by oblique ion-implantation is performed. The impurity is implanted into the semiconductor layer SL through the insulating film IF3.

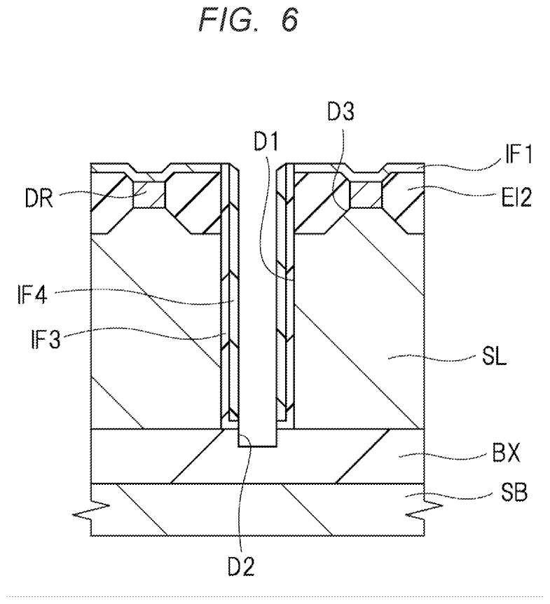

Next, as shown in FIG. 6, the insulating film IF4 is formed (deposited) so as to cover the insulating film IF3 including the trench D1. The insulating film IF4 is made of, for example, silicon oxide. The insulating film IF4 is a PSG (Phosphorus Silicate Glass) film or a TEOS (Tetra Ethyl Ortho Silicate) film. The insulating film IF4 can be formed by, for example, a CVD method. A thickness of the insulating film IF4 is smaller than half of an opening a width between the insulating film IF3 covering the side surface of the trench D1. Therefore, the insulating film IF4 covering the side surface of the trench D1 are separated from each other.

Subsequently, by performing etch-back, portions of each of the insulating films IF3 and IF4 is removed, and the bottom surface of the trench D1 is partially retracted to form the trench D2. In this etch-back step, the insulating films IF4 and IF3 on the upper surface of the semiconductor layer SL are removed in the outside the trench D1 to expose an upper surface of the insulating film IF1. At the bottom of the trench D1, the insulating films IF4 and IF3 are removed by the etch-back, and the upper surface of the BOX film BX is exposed. Furthermore, by continuing the etch-back, part of the upper surface of the BOX film BX is recessed to the middle depth of the BOX film BX. As a result, the trench D2 extending from vicinity of the upper surface of the semiconductor layer SL to the middle depth of the BOX film BX is formed.

That is, after the etch-back for exposing the upper surface of the BOX film BX is performed, the etch-back is further extended. As a result, a width of the trench D2 is widened, so that a void V1 to be described later is easily formed.

In the etch-back, the insulating films IF3 and IF4 covering the side surface of the trench D1 remains without being removed. Further, in the insulating film IF4 covering the side surface of the trench D1, the insulating film IF3 covering the bottom surface of the trench D1 directly under remains without being removed. The side surface of the trench D2 is configured by the side surface of the insulating film IF4, the side surface of the insulating film IF3, and the side surface of the BOX film BX in this order from the top.

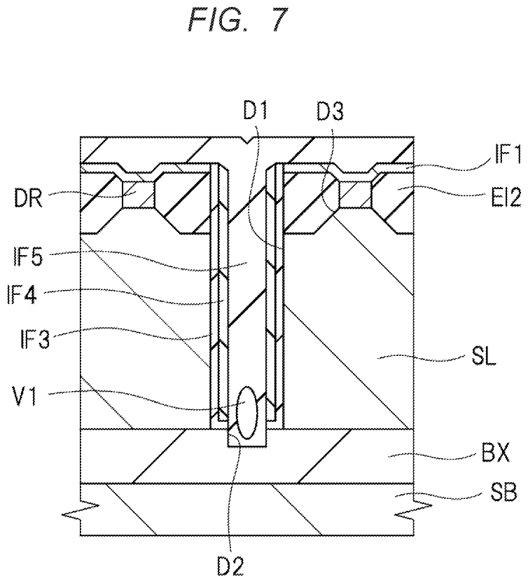

Next, as shown in FIG. 7, the insulating film IF5 is formed on the BOX film BX including the trench D2, on the insulating film IF1, on the insulating film IF3, and on the insulating film IF4 by, for example, a CVD method. Thus, the inside of the trench D2 is filled. A thickness of the insulating film IF5 is half or more of an opening the width of the trench D2. Therefore, the insulating film IF5 covering the side surface of the trench D2 are in contact with each other at a central portion of the trench D2 in the short direction (horizontal direction) of the trench D2. That is, the sum film thickness of the insulating films IF3, IF4 and IF5 covering the side surface of the trench D1 is half or more of the opening the width of the trench D1. A part of the insulating film IF5 covers the upper surface of the insulating film IF1, and the other part fills in the trench D2. The insulating film IF5 is made of, for example, silicon oxide. The insulating film IF5 is a PSG film or a TEOS film.

In the step of forming the insulating film IF5, the insulating film IF5 is formed so that the void V1 is included in the insulating film IF5. The void V1 is formed by increasing the thickness of the insulating film IF5 in the region above the bottom of the trench D2 and closing an inside of the trench D2 in the region before the thickness of the insulating film IF5 covering the surface near the bottom of the trench D2 increases during the formation of the insulating film IF5. A position and shape of the void V1 can be controlled by, for example, changing film formation conditions while forming the insulating film IF5, and thereby changing the film quality of the insulating film IF5 to be formed.

The void V1 is formed in the trench D2 vicinity the bottom of the trench D2. The entire periphery of the void V1 is covered with the insulating film IF5. At least a part of the void V1 is located at the same height as the interface between the insulating film IF3 and the BOX film BX and the interface between the semiconductor layer SL and the BOX film.

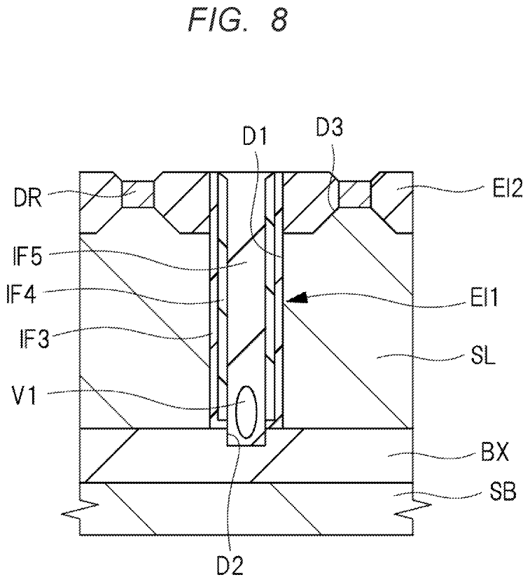

Next, as shown in FIG. 8, the insulating films IF1 and IF5 on the semiconductor layer SL is removed by, for example, CMP (Chemical Mechanical Polishing). As a result, the upper surface of the semiconductor layer SL and the element isolation film EI2 are exposed. By this process, the element isolation film EI1 is formed in the trenches D1 and D2. That is, the insulating films IF3, IF4 and IF5, and the void V1 inside the trenches D1 and D2 configure the element isolation film EI1.

Next, as shown in FIG. 1, impurity ions are implanted into the semiconductor layer SL exposed from the element isolation films EI1 and EI2 by, for example, an ion-implantation method. Thereby, an n-type or p-type semiconductor region DR having a predetermined depth from the upper surface of the semiconductor layer SL is formed. A depth of the semiconductor region DR is, for example, shallower than a depth of the element isolation film EI2. Subsequently, the interlayer insulating film IL mainly made of silicon oxide is formed on the semiconductor layer SL. Thereafter, the upper surface of the interlayer insulating film IL is planarized by, for example, CMP method. Subsequently, the contact plug CP is formed through the interlayer insulating film IL and electrically connected to the semiconductor region DR. Subsequently, the wiring M1 connected to the contact plug CP is formed on the interlayer insulating film IL and the contact plug CP.

Thereafter, although not shown, the SOI substrate is diced and singulated to obtain a plurality of semiconductor chips. This completes the semiconductor device of present embodiment.

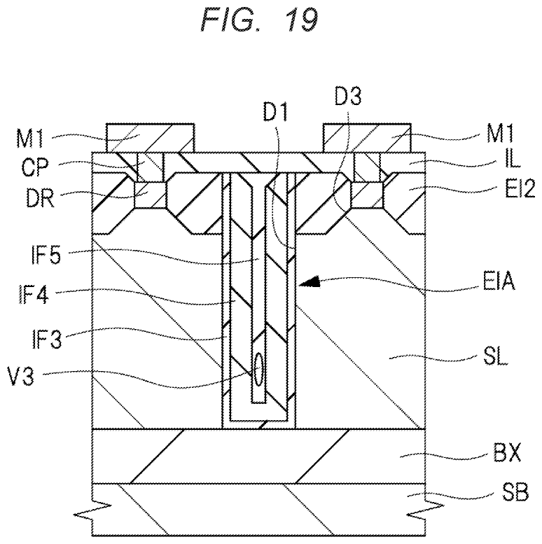

FIG. 19 shows an element isolation film EIA of the semiconductor device as a comparative example. present embodiment. Unlike the semiconductor device of present embodiment, a semiconductor device of the comparative example does not have the trench D2. In the trench D1, the insulating films IF3, IF4 and IF5 are formed in this order from the side surface and the bottom surface thereof, and the inside of the trench D1 is filled. On an upper surface of the BOX film BX at the bottom surface of the trench D1, only the insulating film IF3 formed between both ends of the trench D1 in the lateral direction is in contact. In the trench D1, the insulating film IF5 includes a void V3. However, the void V3 is located above the interface (oxide film interface) between the insulating film IF3 and the BOX film BX. The insulating films IF3, IF4 and IF5, and the void V3 in the trench D1 constitute the element isolation film EIA.

The present inventors found that a leakage current occurs between the semiconductor layer SL laterally separated by the element isolation film EIA when conducting a stress test for element isolation using the semiconductor device of the comparative example. As a result of the analysis, when a width of the bottom of the element isolation film EIA in the short direction (horizontal direction) is small, and when an interface between the element isolation film EIA and the BOX film BX is an interface where the silicon oxide film contacts each other (oxide film interface), occurrence of the leakage current was particularly remarkable. Specifically, when the width in the short direction (lateral direction) of a bottom portion of the element isolation film EIA is equal to or less than about 800 nm, the generation of the leakage current becomes remarkable.

It is considered that the leakage current flows through the interface between the BOX film BX and the insulating film IF3 at the bottom of the trench D1. Therefore, in the present embodiment, as described with reference to FIG. 1, the trench D2 is formed which is dug deeper than the trench D1 and reaches a depth in the middle of the BOX film BX. In addition, the void V3 included in the insulating film IF5 filling the trench D2 is formed at the same height as the interface between the BOX film BX and the insulating film IF3.

Due to a formation of the trench D2 and the insulating film IF5 in the trench D2, a path through which leak current flow (leak path) is a distance obtained by adding an interface between the insulating film IF5 and the BOX film BX to the interface between the BOX film BX and the insulating film IF3. Therefore, in the semiconductor device of present embodiment, since the path through which the leakage current flows is longer than in the comparative example, occurrence of the leakage current can be suppressed.

Further, in the present embodiment, the interface between the BOX film BX and the insulating film IF3 is separated by the trench D2 and is adjacent to each other in the short direction of the trench D1 with the trench D2 interposed therebetween. It is also conceivable that the leakage current may flow through the insulating film IF5 between these interfaces adjacent to each other with the trench D2 interposed therebetween. However, here, the void V3 in the insulating film IF5 is formed at the same height as the interface between the BOX film BX and the insulating film IF3. The void V3 is an area having a higher insulating property than the silicon oxide constituting the insulating film IF5. Therefore, the leakage current that attempts to flow at the shortest distance between the interface between the BOX film BX and the insulating film IF3 adjacent to each other across the trench D2 can be blocked by the void V3.

As described above, an electric isolation performance of the element isolation film is enhanced. That is, the breakdown voltage of the semiconductor device having the DTI can be increased. This enhances a reliability of the semiconductor device.

### Second Embodiment

Hereinafter, an aspect in which a trench that fills an entire element isolation film reaches a middle depth of a BOX film BX will be described.

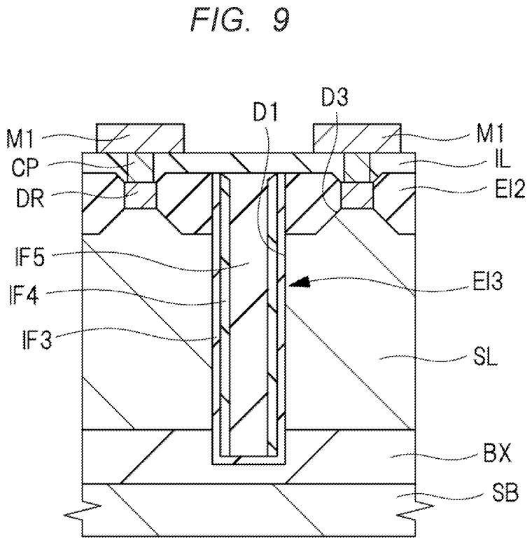

FIG. 9 shows a cross-sectional view illustrating a semiconductor device according to this present embodiment. Structure of the semiconductor device of the present embodiment is similar to structure of the semiconductor device of the first embodiment, except for an element isolation film EI3 formed instead of the element isolation film EI1 and a shape of trench reaching the BOX film BX.

Here, a trench D1 penetrates an element isolation film EI2 and a semiconductor layer SL from an upper surface of the element isolation film EI2 and reaches the middle depth of the BOX film BX. That is, a bottom surface of the trench D1 is located below an interface between the semiconductor layer SL and the BOX film BX. Here, the trench D2 shown in FIG. 1 is not formed. Insulating films IF3, IF4 and IF5 are filled in the trench D1 in this order from a side surface of the trench D1. The upper ends of the insulating films IF3, IF4 and IF5 are located at substantially the same height as an upper surfaces of the element isolation film EI2 and the semiconductor layer SL. The insulating films IF3, IF4 and IF5 are not formed on the upper surfaces of the element isolation film EI2 and the semiconductor layer SL respectively. The insulating film IF5 does not contain any voids.

On the bottom surface of the trench D1, only the insulating film IF3 is in contact with the BOX film BX. That is, the entire bottom surface of the trench D1 is covered with the insulating film IF3. On an upper surface of the insulating film IF3 covering the bottom surface of the trench D1, the insulating film IF4 covering the side surface of the trench D1 is in contact with the insulating film IF5 filling a space between the insulating films IF4. The insulating films IF3, IF4 and IF5 in the trench D1 configure the element isolation film EI3.

One of main features of the present embodiment is that the trench D1 in which the element isolation film EI3 is filled reaches the middle depth of the BOX film BX. Specifically, it is preferable that the interface between the semiconductor layer SL and the BOX film BX and the bottom surface of the trench D1 be 0.3 micrometers or more in a vertical direction. This is because if the distance is less than 0.3 micrometers, the effect of suppressing a leakage current by a long path through which the leakage current flows cannot be effectively obtained. The distance is more preferably 0.5 micrometers or more.

(Method of Manufacturing Semiconductor Device in Second Embodiment)

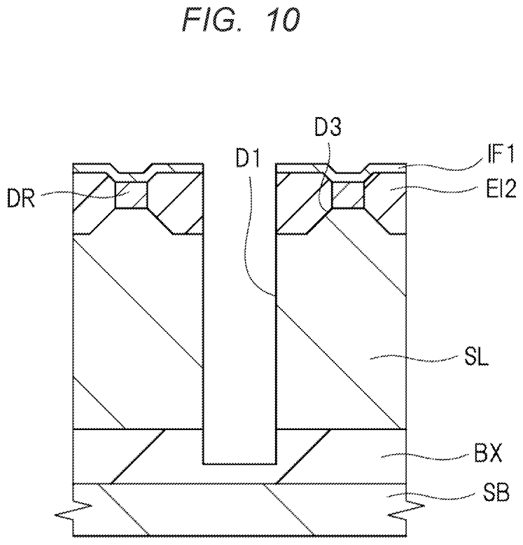

A method of manufacturing semiconductor device according to the second embodiment will be described below with referring to FIGS. 10 to 14 and 9. FIG. 10 to FIG. 14 are cross-sectional views during a manufacturing process of present embodiment.

First, as shown in FIG. 10, the steps described with reference to FIGS. 2 to 4 are performed. As a result, the element isolation film EI2 is formed on an SOI substrate, and the trench D1 that penetrates the element isolation film EI2 and the semiconductor layer SL and reaches an upper surface of the BOX film BX is formed. Subsequently, by performing dry etching using insulating films IF1 and IF2 as a hard mask, the trench D1 is further dug down below the uppermost surface of the BOX film BX. As a result, a depth of the trench D1 is increased, and the bottom surface of the trench D1 reaches the middle depth of the BOX film BX. At this time, the insulating film IF2 on the semiconductor layer SL, which is a hard mask, is also performed etch-back, and a thickness of the insulating film IF2 is reduced.

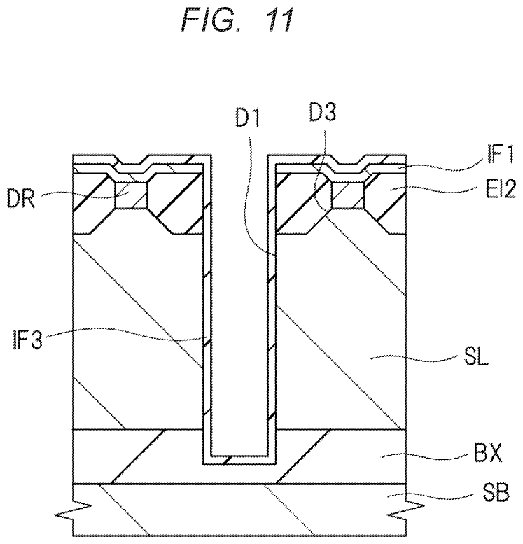

Next, as shown in FIG. 11, a step similar to the process described with reference to FIG. 5 is performed, whereby the insulating film IF3 is formed. That is, after the insulating film IF2 is removed, the insulating film IF3 is formed (deposited) so as to cover the upper surfaces of the element isolation film EI2 and the semiconductor layer SL, and the side surface and the bottom surface of the trench D1. Subsequently, a p-type impurity (for example, B (boron)) is implanted into the side surface of the trench D1 by oblique ion-implantation. The insulating film IF3 is formed so as to cover the side surface and the bottom surface of the trench D1 which is a concave portion of the upper surface of the BOX film BX.

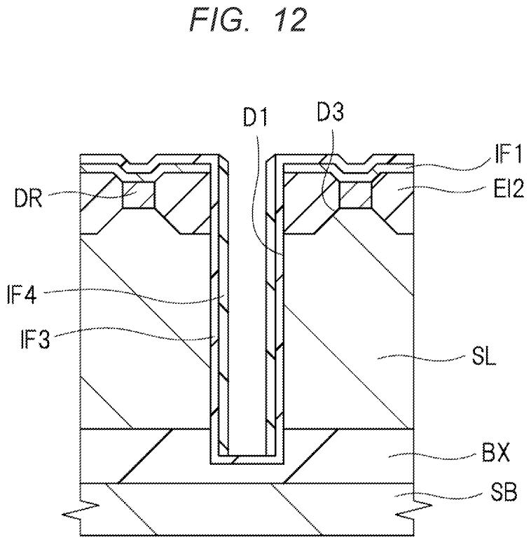

Next, as shown in FIG. 12, the insulating film IF4 is formed (deposited) using, for example, a CVD method. The insulating film IF4 covers the trench D1 and the side surface of the insulating film IF3 in the trench D1 by covering an upper surface of the insulating film IF3. A thickness of the insulating film IF4 is smaller than half of an opening a width between the insulating film IF3 covering the side surface of the trench D1. Therefore, the insulating film IF4 covering the side surface of the trench D1 are separated from each other.

Subsequently, by performing etch-back, the insulating film IF4 on the upper surface of the insulating film IF3 is removed. As a result, the upper surface of the insulating film IF3 is exposed inside and outside the trench D1. That is, a part of the upper surface of the insulating film IF3 covering the bottom surface of the trench D1 is exposed. In the trench D1, the insulating film IF4 covering a side surface of the insulating film IF3 remains without being removed.

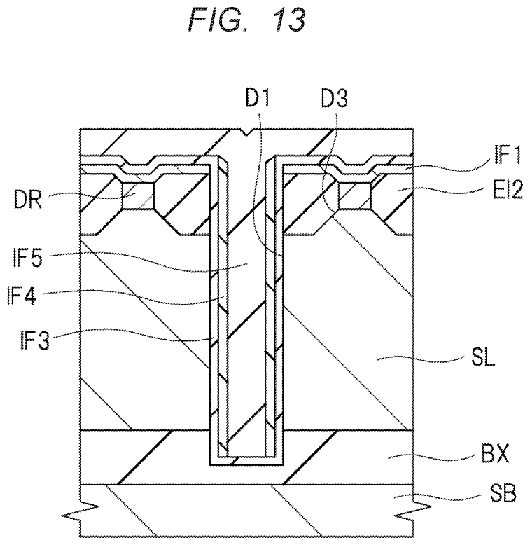

Next, as shown in FIG. 13, the insulating film IF5 is formed on the insulating film IF3 including the trench D1 and on the insulating film IF4 by, for example, a CVD method. Thus, the inside of the trench D1 is filled. A thickness of the insulating film IF5 is half or more of an opening a width between the insulating film IF4 covering the side surface of the trench D1. Therefore, the insulating film IF5 covering the side surface of the trench D1 is in contact with each other at the central portion of the trench D1 in a short direction (lateral direction) of the trench D1. That is, the sum film thickness of the insulating films IF3, IF4 and IF5 covering one side surface of the trench D1 is half or more of an opening a width of the trench D1. The insulating film IF5 outside the trench D1 covers the upper surface of the insulating film IF3, and another part of the insulating film IF5 is filled in the trench D1. In the vicinity of the bottom of the trench D1, the lower end of the insulating film IF5 is in contact with the upper surface of the insulating film IF3.

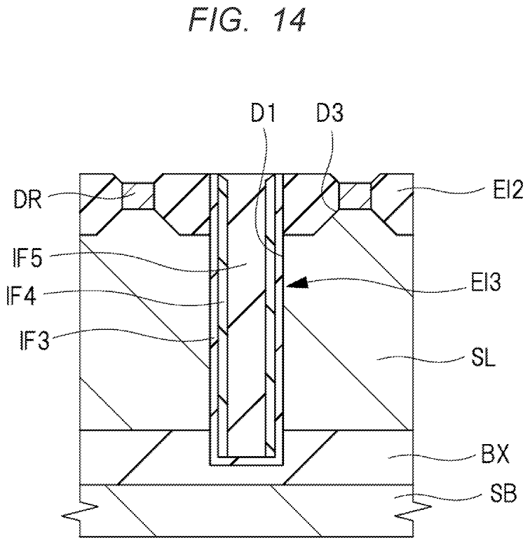

Next, as shown in FIG. 14, the insulating films IF1, IF3 and IF5 on the semiconductor layer SL are removed using, for example, a CMP method. Thereby, the upper surfaces of the semiconductor layer SL and the element isolation film EI2 are exposed. By this process, the element isolation film EI3 is formed in the trench D1. That is, the insulating films IF3, IF4 and IF5 inside the trench D1 constitute the element isolation film EI3.

Next, as shown in FIG. 9, impurity ions are implanted into the semiconductor layer SL exposed from the element isolation films EI3 and EI2 by, for example, an ion-implantation method. Accordingly, an n-type or p-type semiconductor region DR having a predetermined depth is formed from the upper surface of the semiconductor layer SL. Subsequently, an interlayer insulating film IL mainly made of silicon oxide is formed on the semiconductor layer SL. Thereafter, an upper surface of the interlayer insulating film IL is planarized by, for example, a CMP method. Subsequently, a contact plug CP is formed through the interlayer insulating film IL and electrically connected to the semiconductor region DR. Subsequently, a wiring M1 connected to the contact plug CP is formed on the interlayer insulating film IL and the contact plug CP.

Thereafter, although not shown, the SOI substrate is diced and singulated to obtain a plurality of semiconductor chips. This completes the semiconductor device of present embodiment.

In the present embodiment, unlike the first embodiment described above, the trench D1 and the element isolation film EI3 are formed to reach the middle depth of the BOX film BX respectively without forming the trench D2 and the void V1. As a result, when the leak current flow between the semiconductor layer SL separated in the lateral direction by the element isolation film EI3, a leakage current passes through the interface between the BOX film BX and the side and the bottom surface of the insulating film IF3 filled in the trench D1 reaching halfway through the BOX film BX. That is, the leakage current does not flow linearly through an interface between a flat upper surface (uppermost surface) of the BOX film BX and the silicon oxide film in contact with the upper surface, pass through a detour below the flat upper surface of the BOX film BX. That is, in present embodiment, since the path through which the leakage current flows is longer than in a comparative example described with reference to FIG. 19, generation of the leakage current can be suppressed.

Therefore, an electric isolation performance of element isolation film is enhanced. That is, a breakdown voltage of the semiconductor device having the DTI can be increased. This enhances the reliability of semiconductor device.

### Third Embodiment

Hereinafter, an aspect in which a trench that fills an entire element isolation film reaches a middle depth of a BOX film BX and element isolation film contains a void will be described.

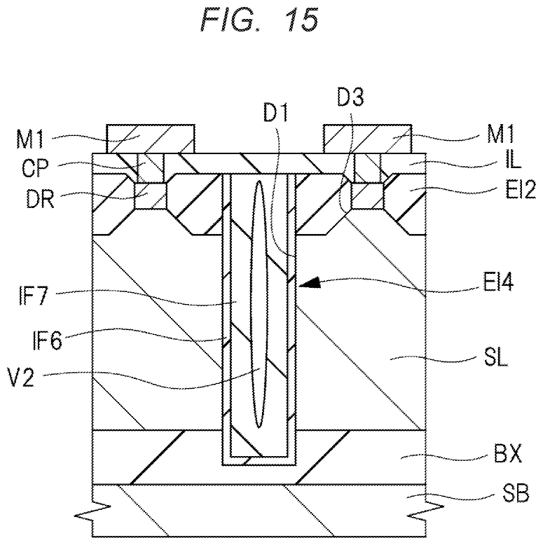

FIG. 15 shows a cross-sectional view illustrating a semiconductor device according to this present embodiment. Structure of the semiconductor device of the present embodiment is similar to structure of the semiconductor device of the first embodiment, except for an element isolation film EI4 formed instead of the element isolation film EI1 and a shape of trench reaching the BOX film BX.

Here, a trench D1 penetrates through the element isolation film EI2 and a semiconductor layer SL from an upper surface of the element isolation film EI2 and reaches the middle depth of the BOX film BX, similarly to the second embodiment. Here, a trench D2 shown in FIG. 1 is not formed. In the trench D1, insulating films IF6 and IF7 is filled in order from a side surface of the trench D1. An upper end of each of the insulating films IF6 and IF7 is located at a height substantially the same as the height of an upper surface of each of the element isolation film EI2 and the semiconductor layer SL. The insulating films IF6 and IF7 is not formed on each of the upper surface of the element isolation film EI2 and the uppermost surface of the semiconductor layer SL. The insulating film IF7 includes a void V2.

On a bottom surface of the trench D1, only the insulating film IF6 is in contact with the BOX film BX. That is, the entire bottom surface of the trench D1 is covered with the insulating film IF6. Only the insulating film IF7 is in contact with an upper surface of the insulating film IF6 covering the bottom surface of the trench D1. Each of the insulating films IF6 and IF7 are made of, for example, silicon oxide. The insulating films IF6 and IF7, and the void V2 in the trench D1 constitute the element isolation film EI4. The entire void V2 is covered with the insulating film IF7 and is separated from the insulating film IF6.

One of the main features of present embodiment is that the trench D1 in which the element isolation film EI4 is filled reaches the middle depth of the BOX film BX. Specifically, it is preferable that an interface between the semiconductor layer SL and the BOX film BX and the bottom surface of the trench D1 be 0.3 micromotors or more in a vertical direction. If the distance is less than 0.3 micromotors, a leakage current suppressing effect by lengthening a path through which the leakage current flows is not obtained effectively. The distance is more preferably 0.5 micromotors or more.

One of main features of present embodiment is that a length from the upper end to the lower end of the void V2 in the vertical direction occupies a large part of the length from the upper end to the lower end of the trench D1 in the vertical direction. That is, a length in the longitudinal direction of the void V2 is larger than a length in the longitudinal direction of the void V1 shown in FIG. 1. Specifically, in the longitudinal direction, the void V2 has a length of 80 percent or more of a length of the trench D1. Here, a part of the void V2 may or may not be at the same height as the interface between the semiconductor layer SL and the BOX film BX. That is, the position of the lower end of the void V2 may be lower or upper than the position of the interface. In this way, the interior of the element isolation film EI4 is hollow over almost the entire length in the vertical direction.

(Method of Manufacturing Semiconductor Device in Third Embodiment)

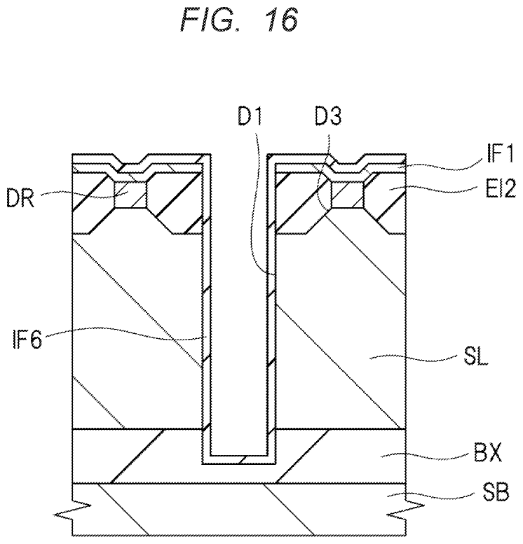

A method of manufacturing a semiconductor device according to the third embodiment will be described below with reference to FIGS. 16 to 18 and 15. FIG. 16 to FIG. 18 are cross-sectional views during the semiconductor device manufacturing process of present embodiment.

First, as shown in FIG. 16, the steps described with reference to FIGS. 10 and 12 are performed. As a result, the element isolation film EI2 on an SOI substrate, the trench D1 that penetrates the element isolation film EI2 and the semiconductor layer SL and reaches the middle depth of the BOX film BX, and an insulating film IF3 are formed. Further, a p-type impurity (for example, B (boron)) is introduced into the side surface of the trench D1. Subsequently, the insulating film IF3 is removed. Here, however, the insulating film IF3 may be left without being removed. Subsequently, the insulating film IF6 is formed so as to cover an upper surface of an insulating film IF1 and cover the side surface and the bottom surface of the trench D1. The insulating film IF6 can be formed using, for example, a CVD method. The insulating film IF6 is made of, for example, silicon oxide. A thickness of the insulating film IF6 is smaller than half of an opening a width of the trench D1. Therefore, the insulating film IF6 covering the side surface of the trench D1 are separated from each other.

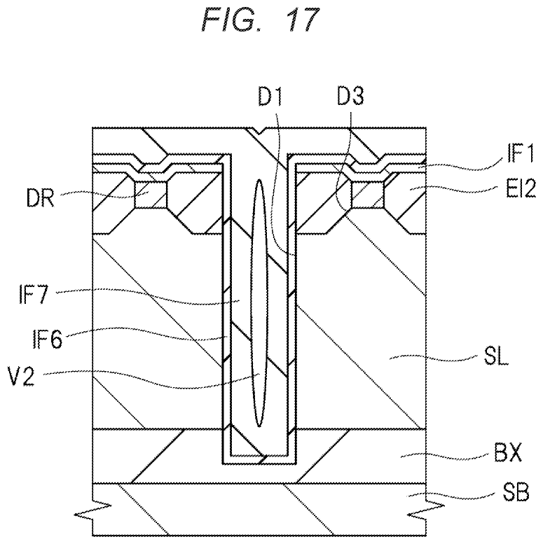

Next, as shown in FIG. 17, the insulating film IF7 is formed on the insulating film IF6 including the trench D1 by, for example, a CVD method. Thus, an inside of the trench D1 is filled. A thickness of the insulating film IF7 is half or more of an opening a width between the insulating film IF6 covering the side surface of the trench D1. Therefore, in a short direction (lateral direction) of the trench D1, the insulating film IF7 covering the side surface of the trench D1 is contacted with each other at the central portion of the trench D1. That is, the sum thickness of the insulating films IF6 and IF7 covering one side surface of the trench D1 is half or more of the opening the width of the trench D1. The insulating film IF7 outside the trench D1 covers the upper surface of the insulating film IF6, and another part of the insulating film IF7 is filled in the trench D1.

In the step of forming the insulating film IF7, the insulating film IF7 is formed so that the void V2 is included in the insulating film IF7. The void V2 is formed by increasing the thickness of the insulating film IF7 of the opening portion of the trench D1 and closing an inside of the trench D1 in the vicinity of an opening portion before the thickness of the insulating film IF7 covering the vicinity of a bottom portion and the opening portion (upper end) of the trench D1 increases during the film formation of the insulating film. A position and shape of the void V2 can be controlled by, for example, changing film formation conditions while forming the insulating film IF7, and thereby changing a film quality of the insulating film IF7 to be formed.

In the longitudinal direction, the void V2 has a length greater than or equal to 80 percent of a length of the trench D1. The void V2 may be located at the same height as each of the interface between the semiconductor layer SL and the BOX film BX, or may be located entirely above the interface.

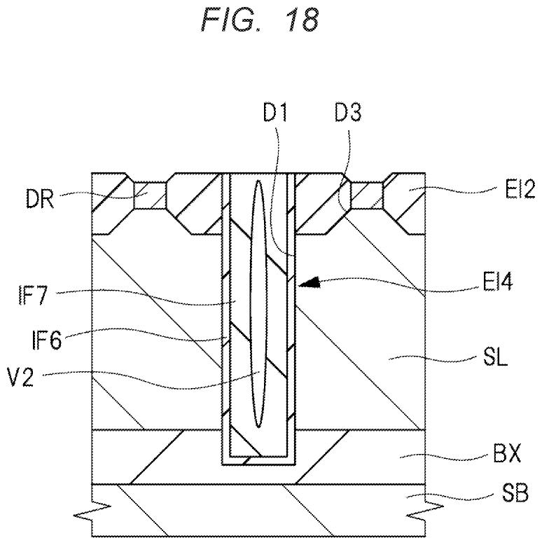

Next, as shown in FIG. 18, the insulating films IF6 and IF7 on the semiconductor layer SL is removed using, for example, a CMP method. This exposes upper surfaces of the semiconductor layer SL and the element isolation film EI2. By this process, the element isolation film EI4 is formed in the trench D1. That is, the insulating films IF6 and IF7 and the void V2 inside the trench D1 constitute the element isolation film EI4.

Next, as shown in FIG. 15, impurity ions are implanted into the upper surface of the semiconductor layer SL exposed from the element isolation films EI4 and EI2 by, for example, an ion-implantation method. Accordingly, an n-type or p-type semiconductor region DR having a predetermined depth is formed from the upper surface of the semiconductor layer SL. Subsequently, an interlayer insulating film IL mainly made of silicon oxide is formed on the semiconductor layer SL. Thereafter, an upper surface of the interlayer insulating film IL is planarized by, for example, CMP method. Subsequently, a contact plug CP is formed through the interlayer insulating film IL and electrically connected to a semiconductor region DR. Subsequently, a wiring M1 connected to the contact plug CP is formed on the interlayer insulating film IL and the contact plug CP.

Thereafter, although not shown, the SOI substrate is diced and singulated to obtain a plurality of semiconductor chips. This completes the semiconductor device of present embodiment.

In present embodiment, as in second embodiment, the trench D1 that reaches the middle depth of the BOX film BX is formed, and the insulating films are filled in the trench D1. As a result, the same advantages as those of second embodiment can be obtained. That is, it is possible to extend the current path when the leakage current flows at the bottom of the element isolation film EI4. Therefore, a breakdown voltage of the semiconductor device can be increased.

In addition, unlike second embodiment described above, the void V2 is formed in the trench D1, which occupies most of the length of the trench D1 in the vertical direction. The void V2 is an area having a higher insulating property than the silicon oxide constituting the insulating film IF7. As a result, in present embodiment, the leakage current which is to flow between SL of the semiconductor layer SL laterally separated by the element isolation film EI4 can be cut off over substantially the entire trench D1 in the vertical direction.

Therefore, the electric isolation performance of element isolation film is enhanced. That is, the breakdown voltage of the semiconductor device having the DTI has been increased, and the invention made by the present inventors has been specifically described based on the embodiments, but the present invention is not limited to the above-described embodiments, and it is needless to say that various changes can be made without departing from the gist thereof.

What is claimed is:

1. A semiconductor device comprising:
a semiconductor substrate;
a first insulating film formed on the semiconductor substrate;
a semiconductor layer formed on the first insulating film;
a first trench penetrated through the semiconductor layer and reached to the first insulating film;
a second insulating film covered a surface of the first trench and contacted to the first insulating film at a bottom of the first trench;
a second trench formed at the bottom of the first trench such that the second trench penetrates through the second insulating film and reached in the first insulating film; and
a third insulating film filled in the first trench and the second trench, wherein
the third insulating film has a void such that the void straddles between the first trench and the second trench.

2. The semiconductor device according to claim 1, wherein
the second insulating film includes:
a fourth insulating film covered a side surface and a bottom surface of the first trench, and a side surface and a bottom surface of the second trench; and
a fifth insulating film filled in the first trench and the second trench via the fourth insulating film.

3. The semiconductor device according to claim 1, further comprising:
a third trench formed on an upper surface of the semiconductor layer and adjacent to the first trench; and
a sixth insulating film filled in the third trench, wherein
a depth of the third trench is shallower than a depth of the first trench.

4. A semiconductor device comprising:
a semiconductor substrate;
a first insulating film formed on the semiconductor substrate;
a semiconductor layer formed on the first insulating film;
a first trench penetrated through the semiconductor layer and reached in the first insulating film;
a second insulating film covered an upper surface of the first trench and contacted to the first insulating film at a bottom of the first trench;
a third insulating film filled in the first trench via the second insulating film.

5. The semiconductor device according to claim 4, wherein
a bottom surface of the first trench is located lower than an interface between the semiconductor layer and the first insulating film in cross-sectional view, and
a distance between the bottom surface of the first trench and the interface of the semiconductor layer and the first insulating film is 0.3 micrometer or more.

6. The semiconductor device according to claim 4, wherein
a third insulating film has a void, and
the void has a length that is 80 percent or more of a length of the first trench in cross-sectional view.

7. The semiconductor device according to claim 6, wherein
the void is formed such that the void straddles the interface of the semiconductor layer and the first insulating film.

8. A manufacturing method of a semiconductor device, comprising steps of:
(a) preparing an SOI substrate configured in which a first insulating film and a semiconductor layer are stacked in this order on a semiconductor substrate;
(b) forming a first trench penetrated through the semiconductor layer and reached to the first insulating film;
(c) forming a second insulating film covered a surface of the first trench and contacted to the first insulating film at a bottom of the first trench;
(d) forming a second trench at the bottom of the first trench such that the second trench penetrates through the second insulating film and reached in the first insulating film; and
(e) forming a third insulating film filled in the first trench and the second trench, wherein
the third insulating film has a void such that the void straddles between the first trench and the second trench.

9. The manufacturing method of the semiconductor device according to claim 8, wherein
the step of (c) includes:
(c1) forming a fourth insulating film covered a side surface and a bottom surface of the first trench, and a side surface and a bottom surface of the second trench; and
(c2) forming a fifth insulating film filled in the first trench and the second trench via the fourth insulating film, and
the second insulating film is configured the fourth insulating film and the fifth insulating film.

10. The manufacturing method of the semiconductor device according to claim 8, further comprising a step of:
(f) forming a third trench on an upper surface of the semiconductor layer and adjacent to the first trench; and
(g) forming a sixth insulating film filled in the third trench, wherein
a depth of the third trench is shallower than a depth of the first trench.

11. A manufacturing method of a semiconductor device, comprising steps of:
(a) preparing an SOI substrate configured in which a first insulating film and a semiconductor layer are stacked in this order on a semiconductor substrate;
(b) forming a first trench penetrated through the semiconductor layer and reached in the first insulating film;
(c) forming a second insulating film covered a surface of the first trench and contacted to the first insulating film at a bottom of the first trench;
(d) forming a third insulating film filled in the first trench via the second insulating film.

12. The manufacturing method of the semiconductor device according to claim 11, wherein
a bottom surface of the first trench is located lower than an interface between the semiconductor layer and the first insulating film in cross-sectional view, and
a distance between the bottom surface of the first trench and the interface of the semiconductor layer and the first insulating film is 0.3 micrometer or more.

13. The manufacturing method of the semiconductor device according to claim 11, wherein
a third insulating film has a void, and
the void has a length that is 80 percent or more of a length of the first trench in cross-sectional view.

14. The manufacturing method of the semiconductor device according to claim 13, wherein
the void is formed such that the void straddles the interface of the semiconductor layer and the first insulating film.
